(19) United States
(12) Patent Application Publication
(10) Pub. No.: US 2014/0313810 A1
(43) Pub. Date: Oct. 23, 2014

(54) SWITCHABLY COUPLED DIGIT LINE SEGMENTS IN A MEMORY DEVICE

(71) Applicant: MICRON TECHNOLOGY, INC., Boise, ID (US)

(72) Inventors: Sangmin Hwang, Boise, ID (US); Tae H. Kim, Boise, ID (US); Hoyoung Kang, Boise, ID (US)

(73) Assignee: Micron Technology, Inc., Boise, ID (US)

(21) Appl. No.: 13/866,693

(22) Filed: Apr. 19, 2013

(51) Int. Cl. G11C 11/401; G11C 11/408

(52) U.S. Cl. CPC G11C 11/401; G11C 11/408
USPC 365/72; 365/230.01

(57) ABSTRACT

A memory array includes segmented global and local digit lines in which the global digit line segments are switchably coupled to one of a plurality of local digit line segments at a time. A sense circuit coupled to a global digit line segment can be switched to sense memory cells coupled to one of the plurality of local digit lines at a first time and memory cells coupled to a second one of the plurality of local digit lines at a second time. Neither the global digit line segments nor the local digit line segments extend through the entire memory array.

### TECHNICAL FIELD

The present embodiments relate generally to memory and a particular embodiment relates to switchably coupled digit line segments in a memory device.

### BACKGROUND

As computer hardware becomes smaller and more powerful, memory manufacturers are under pressure to constantly increase memory density of memory devices. This can be accomplished by making the memory cells smaller and increasing the number of the memory cells in a memory array of an integrated circuit.

FIG. 1 illustrates a typical prior art memory array (e.g., DRAM). The array comprises a plurality of memory cells 100, each memory cell 100 being coupled between an access line (e.g., word line) 103 and a digit line 104.

FIG. 2 illustrates greater detail of a typical prior art DRAM memory cell 100 as used in FIG. 1. The memory cell 100 is formed by a transistor 201 for controlling access to the memory cell 100, and a capacitor 200 that stores the charge. The transistor 201 has a control gate coupled to the word line 205 and is enabled/disabled by the voltage on the word line 205. The drain of the transistor 201 is coupled to the digit line 204. The capacitor 200 is coupled between the source of the transistor 201 and a voltage V_{CC}/2. Access to the digit line 204 by the capacitor 200 can be enabled by a voltage on the word line 205 turning on the transistor 201.

Referring again to FIG. 1, the digit lines 104 are coupled to sense amplifiers/drivers 105 that can sense the states of the memory cells 100. The sensing can occur through sense amplifiers when the memory cell capacitors are coupled to the digit lines through their respective enabled control transistor.

A row decoder 106 is coupled to the word lines 103 to generate the word line signals in response to a row address from a controller. A column decoder 107 is coupled to the sense amplifiers/drivers 105 and generates a column address through drivers onto the digit lines 104 in response to a column address from the controller. The column decoder 107 also outputs the sensed states from the memory cells 100 as well as accepts the data to be stored in the memory cells 100.

FIG. 3 illustrates a schematic diagram showing greater detail of a typical prior art connection between the sense amplifiers and the digit lines. The sense amplifiers 320-322 are coupled to global digit lines 310-312. The global digit lines 310-312 are coupled to respective local digit lines 300-302 that are then coupled to the individual memory cells. The global digit lines 310-312 and the local digit lines 300-302 span the length of the memory array.

Increasing numbers of memory cells on a digit line can cause both longer global and local digit lines that can result in greater resistance and parasitic capacitance for those lines. This can have the effect of slower performance since the greater resistance and capacitance values require longer periods for charging and discharging of the digit lines.

### BRIEF DESCRIPTION OF THE DRAWINGS

FIG. 1 shows a schematic diagram of a typical prior art dynamic random access memory (DRAM) array.

FIG. 2 shows a schematic diagram showing greater detail of a typical prior art DRAM cell in accordance with the embodiment of FIG. 1.

FIG. 3 shows a schematic diagram showing greater detail of a typical prior art 4F2 vertical transistor DRAM sense amplifier connection in accordance with the embodiment of FIG. 1.

FIG. 4 shows a schematic diagram of one embodiment of memory sense amplifier connections.

FIG. 5 shows a more detailed view of a section of the schematic diagram of the embodiment of FIG. 4.

FIG. 6 shows a timing diagram of one embodiment of a method for operating a memory device in accordance with the embodiments of FIGS. 4-5.

FIG. 7 shows a flowchart of one embodiment of a method for operating a memory device in accordance with the embodiments of FIGS. 4-6.

FIG. 8 shows a block diagram of one embodiment of a memory system.

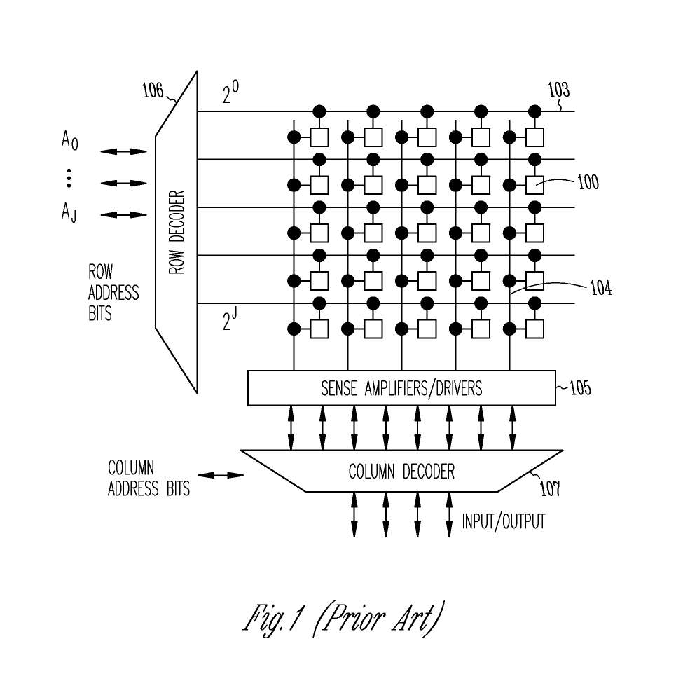

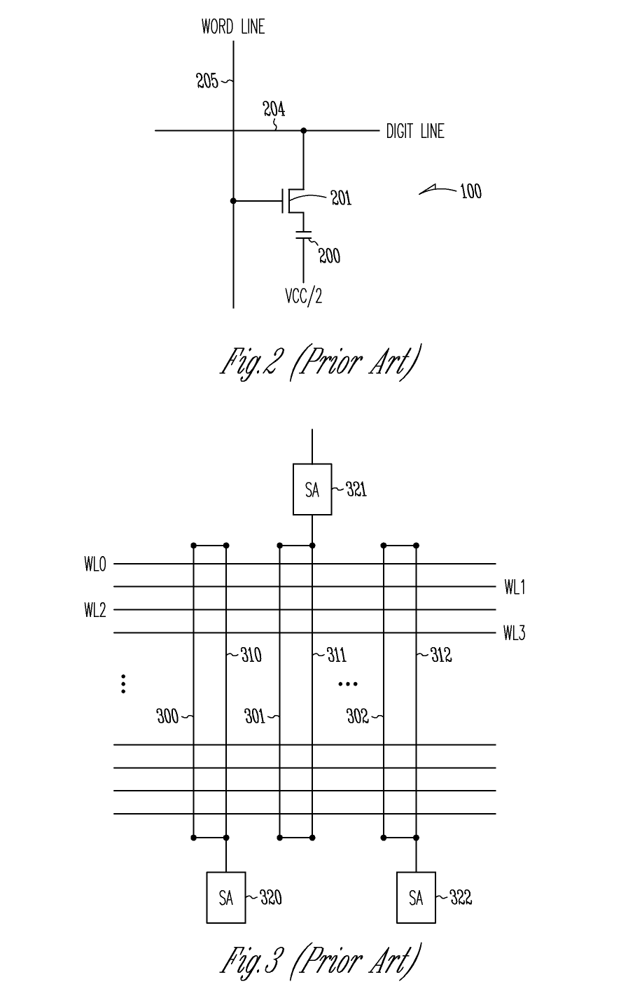

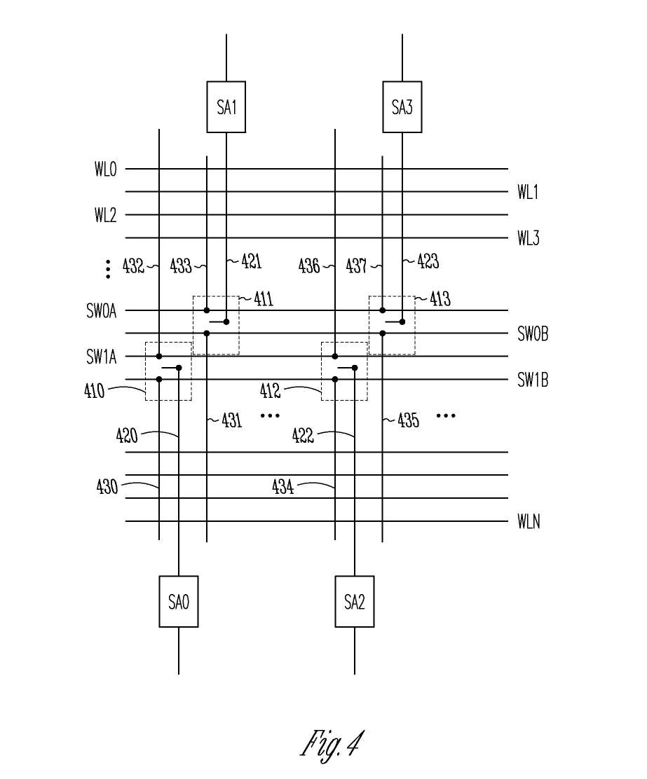

### DETAILED DESCRIPTION

In the following detailed description, reference is made to the accompanying drawings that form a part hereof and in which is shown, by way of illustration, specific embodiments. In the drawings, like numerals describe substantially similar components throughout the several views. Other embodiments may be utilized and structural, logical, and electrical changes may be made without departing from the scope of the present disclosure. The following detailed description is, therefore, not to be taken in a limiting sense.

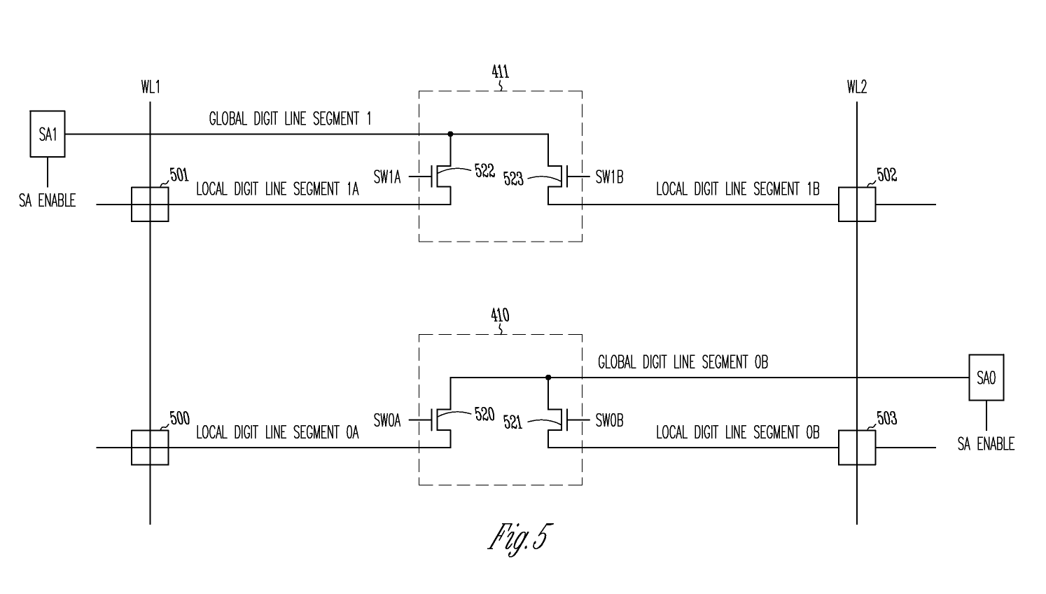

FIG. 4 illustrates a schematic diagram of one embodiment of memory sense amplifier connections. The embodiment of FIG. 4 provides switching 410-412 in the middle of the array such that the global digit lines and local digit lines are approximately half of the length of typical prior art digit lines. In other words, instead of the global and local digit lines running the entire length of the memory array, the global and local digit lines are divided into shorter lengths so that they no longer extend across the entire memory array. This can result in reduced capacitance for those lines with a resulting improvement in performance.

The subsequently described embodiment of FIG. 4 illustrates the digit line switching being located substantially in the middle of the digit lines. Alternate embodiments might provide additional switching for each digit line such that each of the digit lines are divided up into more than two shorter segments.

The embodiment of FIG. 4 includes sense circuitry (e.g., sense amplifiers) SA0-SA3 that provides a sensing capability for determining a state (e.g., logical 1 or logical 0) of an addressed memory cell. Global digit lines 420-423, subsequently referred to as global digit line segments 420-423, are coupled to their respective sense circuitry SA0-SA3. The global digit line segments 420-423 are each coupled to a respective switch 410-413.

In one embodiment, the switches 410-413 are switching transistors. Each switch 410-413 can include a pair of transistors that can be enabled by switch control signals as described subsequently.

The local digit lines 430-437, subsequently referred to as local digit line segments, are each coupled to a plurality of memory cells (not shown). In one embodiment each plurality of memory cells can be referred to as a column of memory cells. Similarly, the word lines WL0-WLn are each coupled to another plurality of memory cells that can be referred to as a row of memory cells.

The local digit line segments 430-437 are each coupled to a respective one of the switches 410-413. For example, switch 410 is coupled to global digit line segment 420 that is coupled to sense amplifier SA0. Local digit line segments 430, 432 are coupled to the switch 410 such that the switch 410 can connect either a first local digit line segment 430 to the sense amplifier SA0 or a second local digit line segment 432 to the sense amplifier SA0. Switch 411 is coupled to global digit line segment 421 that is coupled to sense amplifier SA1. Local digit line segments 431, 433 are coupled to the switch 411 such that the switch 411 can connect either a first local digit line segment 431 to the sense amplifier SA1 or a second local digit line segment 433 to the sense amplifier SA0. Switch 412 is coupled to global digit line segment 422 that is coupled to sense amplifier SA2. Local digit line segments 434, 436 are coupled to the switch 412 such that the switch 412 can connect either a first local digit line segment 434 to the sense amplifier SA2 or a second local digit line segment 436 to the sense amplifier SA2. Switch 413 is coupled to global digit line segment 423 that is coupled to sense amplifier SA3. Local digit line segments 435, 437 are coupled to the switch 413 such that the switch 413 can connect either a first local digit line segment 435 to the sense amplifier SA3 or a second local digit line segment 437 to the sense amplifier SA3.

The position of the switches 410-413 can be controlled by a pair of switch control signals SW0a, SW0b, SW1a, SW1b. For example, switch control signal SW0a can control the connection of local digit line segments 433, 437 to their respective global digit line segments 421, 423 through switches 411, 413. Switch control signal SW0b can control the connection of local digit line segments 431, 435 to their respective global digit line segments 421, 423 through switches 411, 413. Switch control signal SW1a can control the connection of local digit line segments 432, 436 to their respective global digit line segments 420, 422 through switches 410, 412. Switch control signal SW1b can control the connection of local digit line segments 430, 434 to their respective global digit line segments 420, 422 through switches 410, 412.

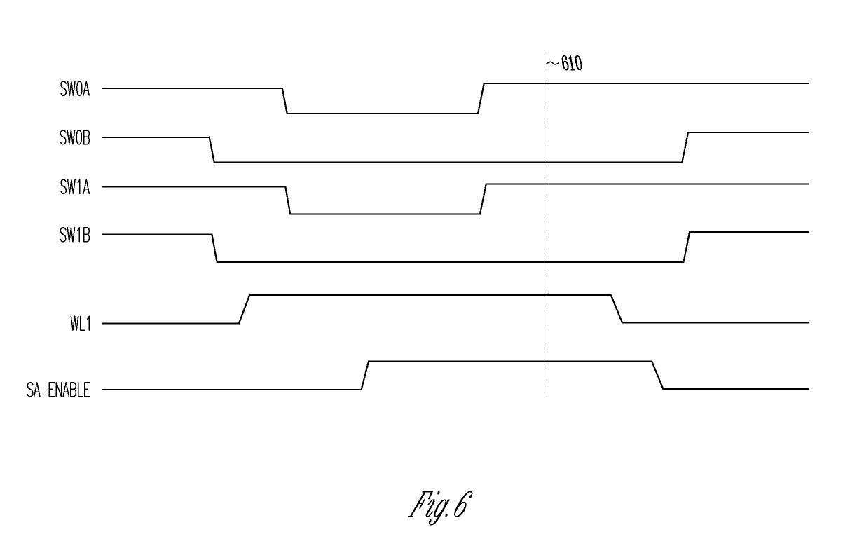

FIG. 5 illustrates a schematic diagram of one embodiment of two of the switches 410, 411 of FIG. 4. This figure shows a more detailed view of two of the sense circuitry SA0, SA1 of FIG. 4 with two of the switches 410, 411 as part of an array of memory cells 500-503.

In one embodiment, the switches 410, 411 include switching transistors 520-523 that control coupling of the local digit line segments to their respective global digit line segment. The switch control signals SW0a, SW0b, SW1a, SW1b can be coupled to a gate of their respective transistor. The subsequent discussion of the operation of the switches 410, 411 assumes that the transistors 520-523 are turned on when their respective control signals SW0a, SW0b, SW1a, SW1b are at a positive voltage (e.g., logical high) and turned off when their respective control signals SW0a, SW0b, SW1a, SW1b are at a ground voltage (e.g., logical low). This is for purposes of illustration only as alternate embodiments may have different types of transistors that use ground, or negative voltages, (e.g., logical low) to turn on the transistors and positive voltages (e.g., logical high) to turn off the transistors.

The circuit diagram of FIG. 5 shows sense amplifier SA0 coupled to global digit line segment 0b that goes to switch 410. Global digit line segment 0 can be switched between local digit line segment 0a and local digit line segment 0b through switch 410. Switch control signal SW0a controls the connection of global digit line segment 0 to local digit line segment 0a. Switch control signal SW0b controls the connection of global digit line segment 0 to local digit line segment 0b.

Sense amplifier SA1 is coupled to global digit line segment 1 that goes to switch 411. Global digit line segment 1 can be switched between local digit line segment 1a and local digit line segment 1b through switch 411. Switch control signal SW1a controls the connection of global digit line segment 1 to local digit line segment 1a. Switch control signal SW1b controls the connection of global digit line segment 1 to local digit line segment 1b.

FIG. 5 further shows a first memory cell 500 coupled to a first local digit line segment 0a and a second memory cell 501 coupled to a second local digit line segment 1a. The memory cells 500, 501 are shown coupled to the same word line. Additional memory cells 502, 503 are shown coupled to the other local digit line segments and another word line WL2.

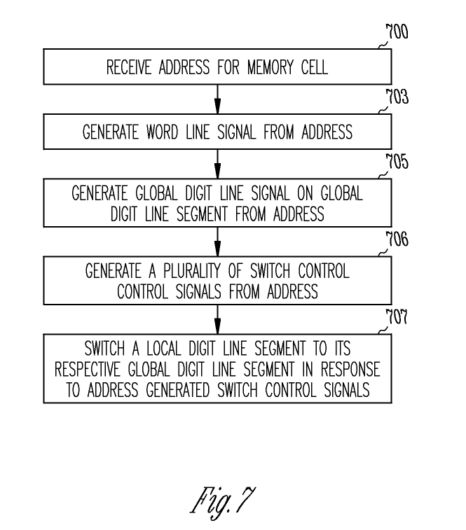

FIG. 6 illustrates a timing diagram of the switching control signals SW0a, SW0b, SW1a, SW1b, a word line WL1 read signal, and sense amplifier enable signal SA ENABLE. In one embodiment, when the switch control signals are at a logical high, their respective transistor (e.g., switch) is turned on, thus connecting the desired local digit line segment to its respective global digit line segment. In one embodiment, the word line read signal WL1 is at a positive voltage (e.g., logical high) when it is desired to read the memory cells coupled to the word line WL1. The sense amplifiers can also be enabled by a positive voltage on the SA ENABLE signal.

Referring to both the schematic diagram of FIG. 5 and the timing diagram of FIG. 6, it can be seen that the memory cells 500, 501 can be read by their respective sense amplifiers SA0, SA1 when SW0a and SW1a, WL1, and SA ENABLE are at logical highs. Switch control signals SW0b and SW1b are at logical lows so that their respective switches are turned off and their respective local digit line segments are not connected to the global digit line segments. It can be seen that only one of the plurality of local digit line segments is connected to its respective global digit line segment at one time 610 during a read operation (e.g., WL1 and SA ENABLE at a logical high).

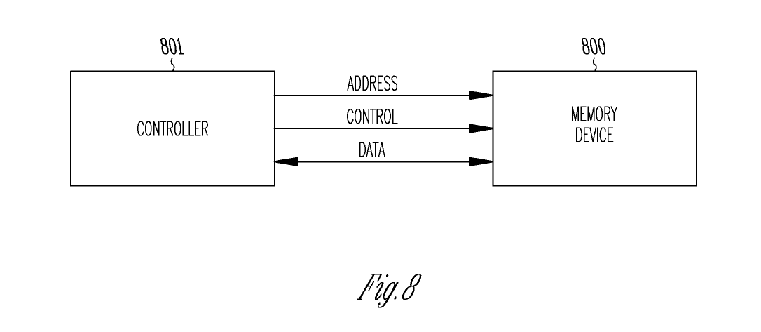

FIG. 7 illustrates a flowchart of one embodiment of a method of operation of a memory device in accordance with the embodiments of FIGS. 4-6. The method includes the memory device receiving an address from a controller for accessing (e.g., reading, programming) at least one memory cell. A row decoder of the memory device decodes the received address and generates a word line signal from the address 703. A column decoder of the memory device decodes the received address and generates, from the address, a global digit line signal that is output on a global digit line segment 705. The received address can also be used to generate switching signals 706, such as switch control signals SW0a, SW0b, SW1a, SW1b, that control the switches. A local digit line segment is then switched to its respective global digit line segment based on a switch control signal generated from the received address 707.

FIG. 8 illustrates a block diagram of one embodiment of a memory system that can include a memory device in accordance with the embodiments of FIGS. 4-7. The memory system includes a memory device 800 having a memory array that can use the global digit line segments that are switchably coupled to only one of at least two local digit line segments, as illustrated in FIGS. 4 and 5. The memory device 800 is coupled to a controller (e.g., microprocessor, control circuitry) 801 over address, data, and control buses. The controller 801 is configured to control the memory system by generating addresses and control signals. In one embodiment, the controller 801 can be internal control circuitry to the memory device and be configured to generate control signals such as the switch control signals.

### CONCLUSION

One or more embodiments employ segmented global and local digit lines in a memory array so that neither of the global or local digit line segments extend through all of the memory array. A sense circuit is coupled to each global digit line segment. The sense circuit can then be switchably coupled to one of a plurality of local digit line segments, through its respective global digit line segment, during a sense operation.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention.

1. A memory device comprising:
a plurality of memory cells;
a plurality of local digit line segments, each local digit line segment coupled to a group of memory cells of the plurality of memory cells; and
a global digit line segment switchably coupled to the plurality of local digit line segments wherein the global digit line segment is coupled to only one of the plurality of local digit line segments at any one time and wherein the global digit line segment extends through only a portion of a length of an array of the plurality of memory cells, where the portion of the length of the array is less than the entire length of the array of the plurality of memory cells.

2. The memory device of claim 1 wherein the memory cells are dynamic random access memory cells.

3. The memory device of claim 1 and further comprising a sense circuit coupled to the global digit line segment.

4. The memory device of claim 3 wherein the sense circuit is configured to sense only one of the plurality of local digit line segments at any one time.

5. The memory device of claim 1 wherein each of the plurality of local digit line segments does not extend across an entire array of the plurality of memory cells.

6. (canceled)

7. The memory device of claim 1 and further comprising a switch configured to switchably couple the global digit line segment to only one of the plurality of local digit line segments at any one time.

8. The memory device of claim 7 wherein the switch comprises a plurality of transistors, each transistor coupled between the global digit line segment and a different one of the plurality of local digit line segments.

9. A memory device comprising:
an array of memory cells;
a plurality of local digit line segments, each local digit line segment coupled to a group of memory cells of the array of memory cells;
a plurality of global digit line segments, each global digit line segment coupled to a different one of a plurality of sense circuits, wherein each of the plurality of global digit line segments extend through only half a length of the array of memory cells; and
a plurality of switches, each switch coupled to a respective one of the plurality of global digit line segments and configured to couple the respective global digit line segment to only one of at least two of the plurality of local digit line segments at any one time.

10. The memory device of claim 9 wherein the group of memory cells is less than an entire column of memory cells of the array of memory cells.

11. The memory device of claim 10 wherein each switch is coupled to control circuitry configured to generate a plurality of switch control signals.

12. The memory device of claim 11 wherein a first switch control signal of the plurality of switch control signals enables a switch to couple the respective global digit line segment to a first local digit line segment and a second switch control signal of the plurality of switch control signals disables the switch from coupling the respective global digit line segment to a second local digit line segment.

13. The memory device of claim 12 wherein the first switch control signal is coupled to a gate of a first transistor of the switch and the second switch control signal is coupled to a gate of a second transistor of the switch.

14. The memory device of claim 13 wherein the respective global digit line segment is coupled to both the first and the second transistors.

15. A method for operating a memory device having a global digit line segment switchably coupled to a plurality of local digit line segments in an array of memory cells, the method comprising:
receiving an address for a memory cell coupled to a local digit line segment of the plurality of digit line segments that do not extend across an entire length of the array of memory cells;
generating a word line signal in response to the address;
generating a global digital line signal on the global digit line segment, that does not extend across the entire length of the array of memory cells, in response to the address; and
switching the local digit line segment to the global digit line segment in response to the address.

16. The method of claim 15 wherein switching the local digit line segment comprises generating a plurality of switch control signals in response to the address.

17. The method of claim 16 wherein the global digit line segment is coupled to a switch comprising a first transistor and a second transistor and the method further comprising enabling the first transistor in response to a first switch control signal of the plurality of switch control signals while substantially simultaneously disabling the second transistor in response to a second switch control signal of the plurality of switch control signals.

18. The method of claim 15 wherein the local digit line segment is a first local digit line segment and switching the first local digit line segment to the global digit line segment comprises switching a second local digit line segment such that it is not coupled to the global digit line.

19. A memory system comprising:
a controller configured to control the memory system; and
a memory device coupled to the controller, the memory device comprising:
an array of memory cells; and
a sense circuit switchably coupled to a group of memory cells of the array of memory cells, the group of memory cells coupled to a local digit line segment of a plurality of local digit line segments, the sense circuit switchably coupled through a global digit line segment to only the local digit line segment, wherein the global digit line segment does not extend through all of a length of the array of memory cells.

20. The memory system of claim 19 wherein the memory device is configured to generate switch control signals in response to a received address from the controller.

21. The memory system of claim 20 and further comprising a switch having a plurality of transistors, each transistor configured to couple a different one of the plurality of local digit line segments to the sense circuit at one time.
